(19) United States
(12) Patent Application Publication
(10) Pub. No.: US 2015/0096239 A1
(43) Pub. Date: Apr. 9, 2015

(54) IN-WALL ENCLOSURE

(71) Applicant: MILESTONE AV TECHNOLOGIES LLC, Eden Prairie, MN (US)

(72) Inventor: Harlow Frogness, Eden Prairie, MN (US)

(73) Assignee: MILESTONE AV TECHNOLOGIES LLC, Eden Prairie, MN (US)

(21) Appl. No.: 14/508,429

(22) Filed: Oct. 7, 2014

Related U.S. Application Data
(60) Provisional application No. 61/888,987, filed on Oct. 9, 2013.

(51) Int. Cl. F16M 13/02; H05K 5/02; E04F 19/08

(52) U.S. Cl. CPC F16M 13/022; E04F 19/08; H05K 5/0217
USPC 52/27; 248/231.91; 174/481

(57) ABSTRACT

An enclosure adapted to be received in a stud-wall includes a pair of opposing side walls, a pair of opposing end walls disposed adjacent and perpendicular to the side walls, a back wall, and an open front, each of the sides walls and each of the end walls having a permanently detachable portion along a margin thereof adjacent the open front. At least one of the end walls or at least one of the side walls may have a permanently removable knock-out portion defined therein.

### RELATED APPLICATIONS

This application claims the benefit of U.S. Provisional Patent Application No. 61/888,987, entitled IN-WALL ENCLOSURE and filed Oct. 9, 2013, said application being hereby fully incorporated herein by reference.

### FIELD OF THE INVENTION

The present invention relates to mounts for flat panel displays and associated accessories, and more particularly to in-wall mounts for flat panel displays and accessories.

### BACKGROUND OF THE INVENTION

Flat panel electronic displays have become very popular due to their compact size, desirable aesthetics, and superior performance. The inherent form factor and weight advantages of these displays have made large screen sizes economically and practically feasible, leading to rapidly increasing demand for these large screens.

Often, it is desirable to mount a flat panel display from a fixed structure such as a wall, ceiling, column or other structural feature. Consequently, specialized mounts have been developed to enable displays to be mounted from fixed structures, while also enabling selective positioning of the display for visibility or convenience.

One of the desirable aesthetic aspects of flat panel displays is the flat appearance of the display when mounted on a wall—resembling a framed photograph or painting. In order to enhance this flat appearance, it is desirable for the mounting structure to enable the rear side of the display to be mounted as close as possible to the wall surface. While very low profile fixed mounts have been developed, it is often desirable for the mount to enable selective positioning of the display. Such positionable mounts typically are thicker in depth and result in the back of the display being mounted further from the wall surface. For such mounts, it is desirable for the mount to be attached in a recess in the wall surface.

In-wall recessed mounts are typically disposed in a recess formed in a wall between the wall framing studs. A limitation of the present in-wall enclosures that facilitate such mounting is that they are of a fixed depth. That is, different enclosures must be used, depending on the thickness of the wall in which the enclosure is to be mounted. For example, for a 6 inch thick wall, such as is found on exterior walls of residential structures, the enclosure will be made with a depth to fit the 5½ inch actual dimension of the stud with the ½ inch drywall typically provided on the inside. Interior partitions, however, will typically be 4 inches in nominal thickness, with a 3½ inch stud and 1/2 inch drywall. Consequently, it is necessary to stock and provide enclosures of multiple different depth dimensions.

There is a need in the industry for an in-wall enclosure facilitating mount installation that may be selectively adjusted for different wall thicknesses.

### SUMMARY OF THE INVENTION

The in-wall enclosure of the present invention substantially meets the aforementioned need of the industry. In an embodiment, an enclosure adapted to be received in a stud-wall includes a pair of opposing side walls, a pair of opposing end walls disposed adjacent and perpendicular to the side walls, a back wall, and an open front, each of the sides walls and each of the end walls having a permanently detachable portion along a margin thereof adjacent the open front. At least one of the end walls or at least one of the side walls may have a permanently removable knock-out portion defined therein.

In an embodiment of the enclosure, each of the permanently detachable portions may define a predetermined width dimension corresponding to a difference between standard wall thickness dimensions. In an embodiment, the predetermined width dimension may be two inches. In another embodiment, the predetermined width dimension may be four inches.

The back wall of the enclosure of claim may include a plurality of mounting device attachments. Moreover, each permanently detachable portion may define a plurality of separate permanently detachable portions.

In an embodiment, a wall structure includes a plurality of spaced-apart studs, a drywall membrane on the spaced-apart studs, and an enclosure disposed between a pair of the spaced-apart studs. The enclosure can include a pair of opposing side walls, a pair of opposing end walls disposed adjacent and perpendicular to the side walls, a back wall, and an open front. Each of the side walls and each of the end walls of the enclosure have a permanently detachable portion along a margin thereof adjacent the open front. At least one of the end walls of the enclosure may have a permanently removable knock-out portion defined therein, and at least one of the side walls of the enclosure may have a permanently removable knock-out portion defined therein.

In an embodiment of the wall structure, each of the permanently detachable portions of the enclosure may define a predetermined width dimension corresponding to a difference between standard wall thickness dimensions. In an embodiment, the predetermined width dimension can be two inches. In another embodiment, the predetermined width dimension can be four inches.

In an embodiment, the back wall of the enclosure may have a plurality of mounting device attachments. Moreover, each permanently detachable portion can define a plurality of separate permanently detachable portions.

In a further embodiment, a mounting system for an electronic display includes an enclosure adapted to be received in a stud-wall, the enclosure having a pair of opposing side walls, a pair of opposing end walls disposed adjacent and perpendicular to the side walls, a back wall, and an open front, with each of the sides walls and each of the end walls having a permanently detachable portion along a margin thereof adjacent the open front. A display mount is attached to the back wall of the enclosure, the display mount adapted to receive an electronic display thereon. At least one of the end walls of the enclosure may have a permanently removable knock-out portion defined therein, and at least one of the side walls of the enclosure may have a permanently removable knock-out portion defined therein. Each of the permanently detachable portions of the enclosure can define a predetermined width dimension corresponding to a difference between standard wall thickness dimensions.

### BRIEF DESCRIPTION OF THE DRAWINGS

The invention may be more completely understood in consideration of the following detailed description of various embodiments of the invention in connection with the following drawings, in which:

FIG. 1 is a front isometric view of an in-wall enclosure according to an embodiment of the invention;

FIG. 2 is a front elevation view of the enclosure of FIG. 1;

FIG. 3 is a right side elevation view of the enclosure of FIG. 1;

FIG. 4 is a top plan view of the enclosure of FIG. 1;

FIG. 5 is a front isometric view of the enclosure of FIG. 1 installed in a wall of a first thickness;

FIG. 6 is a front isometric view of the enclosure of FIG. 1 installed in a wall having a thickness less than the thickness of the wall of FIG. 5;

FIG. 7 is a front isometric view of an in-wall enclosure according to an alternative embodiment of the invention; and

FIG. 8 is a rear isometric view of an electronic display and mount usable with the enclosure of FIG. 1.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION OF THE PREFERRED EMBODIMENTS

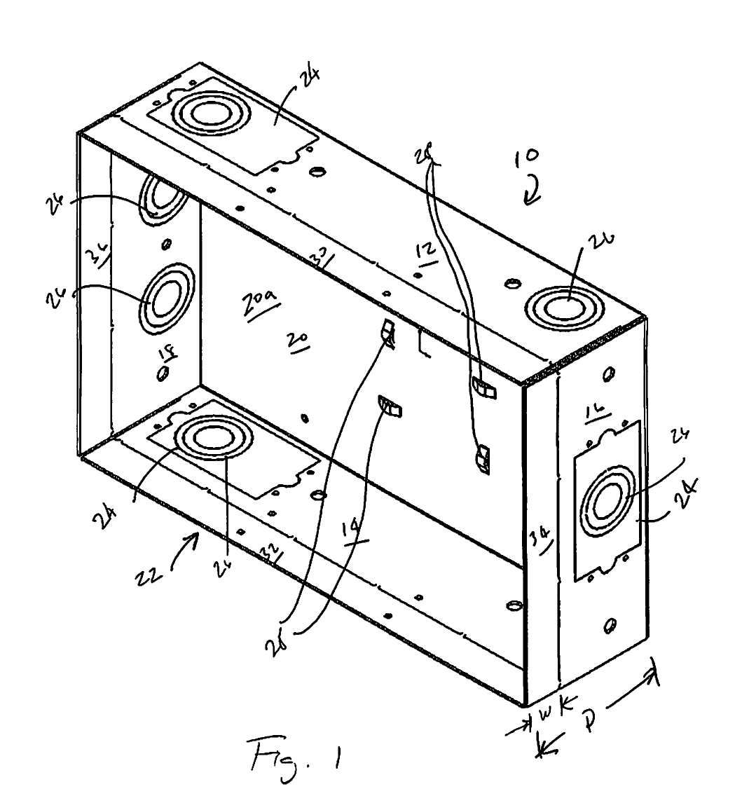

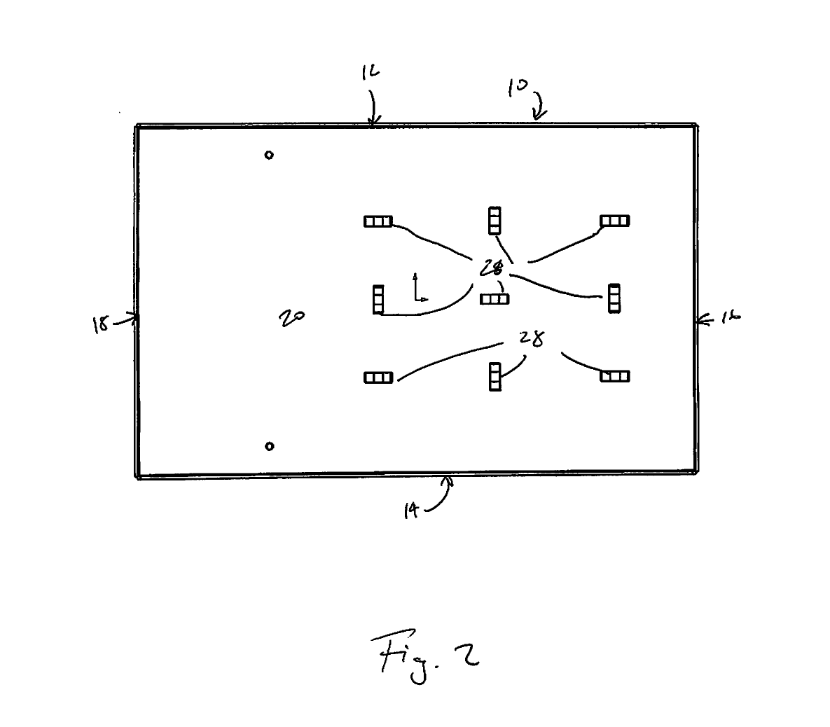

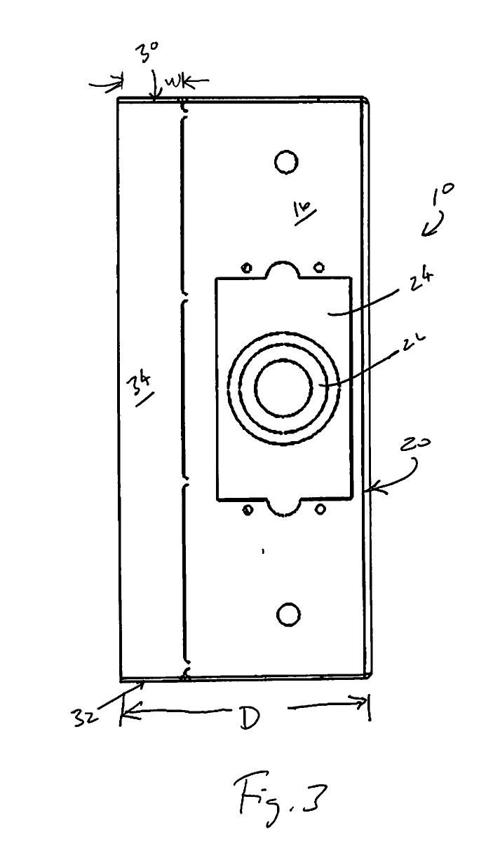

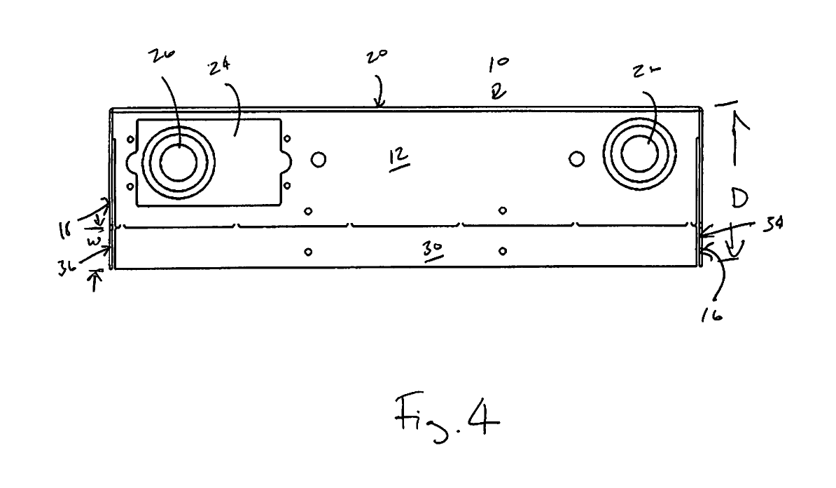

In FIGS. 1-8, there is depicted an in-wall enclosure for mounting an electronic display device 101 such as a television or monitor. Enclosure 10 generally includes top wall 12, bottom wall 14, side walls 16, 18, and back wall 20, and with the enclosure having an open front 22. Top wall 12 and bottom wall 14 may include knock-outs 24 for a standard electrical receptacle, and knock-outs 26 for conduit connections, as are commonly known in the an. Mounting attachments 28 may be provided on or in back wall 20 to receive a mount for a display. Further details of the general construction and use of an in-wall enclosure for a display mount such as disclosed herein are disclosed in U.S. Pat. No. 7,866,622, which is owned by the owners of the present application, said patent being hereby fully incorporated herein by reference.

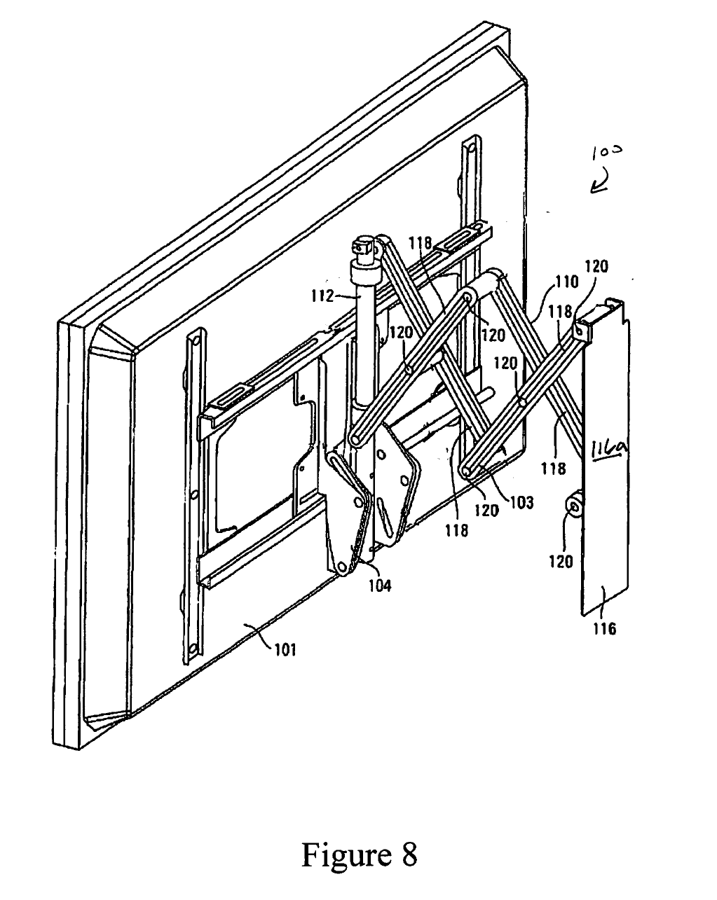

A display mount assembly 100 suitable for use with enclosure 10 is depicted in FIG. 8. Mount assembly 100 generally includes support structure 103, tilt head 104, and display interface structure 106. Support structure 103 generally includes extendable arm assembly 110, support column assembly 112, and swing limit cam 114. Extendable arm assembly 110 generally includes interface 116 and arms 118, pivotally coupled together at pivots 120. In use, back surface 116a of interface 116 is received on insider surface 20a of back wall 20 of enclosure 10 with mounting attachments 28, and with arm assembly 110 extending outwardly through open front 22. Further details of display mount assembly 100 can be found in U.S. Pat. No. 8,508,918 which is owned by the owner of the present application, said patent being hereby fully incorporated herein by reference. It will be appreciated that any other display mount capable of being received on back wall 20 may also be used with enclosure 10.

Importantly, each of top wall 12, bottom wall 14, and side walls 16, 18, have detachable portions 30, 32, 34, 36, respectively, each having width W. By permanently detaching portions 30, 32, 34, 36, (as is commonly known for removing knock-outs in electrical boxes as with knock-outs 24, 26) the depth D of the enclosure can be adjusted for different wall thicknesses.

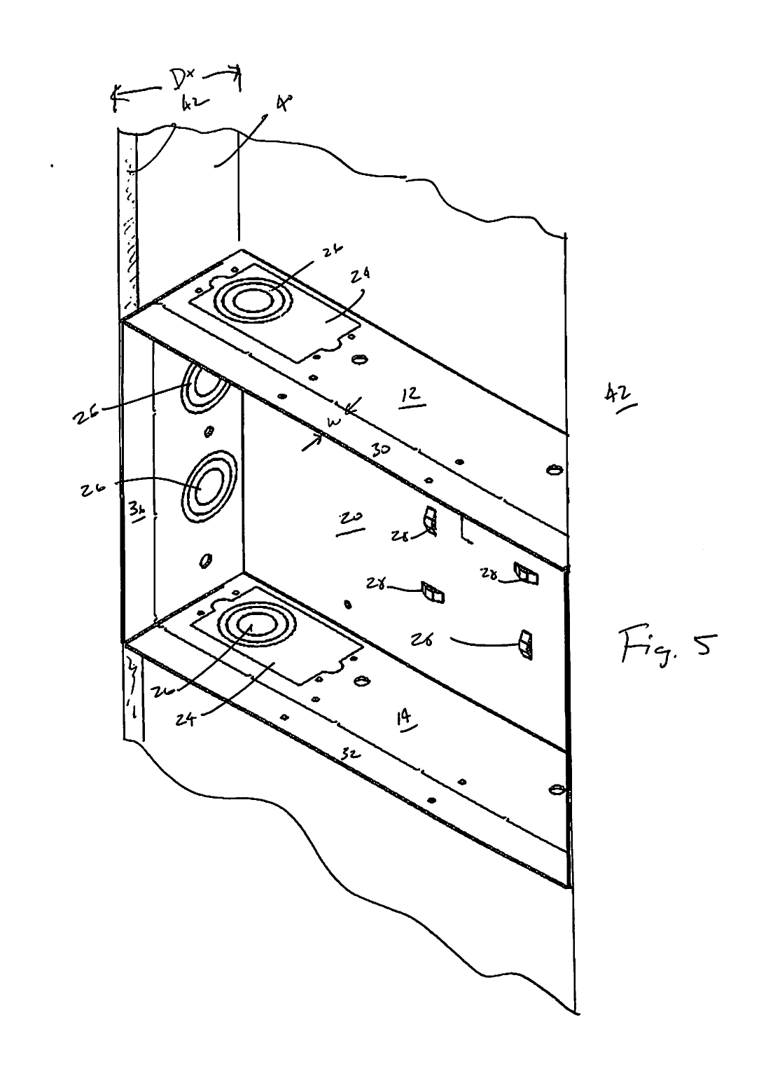

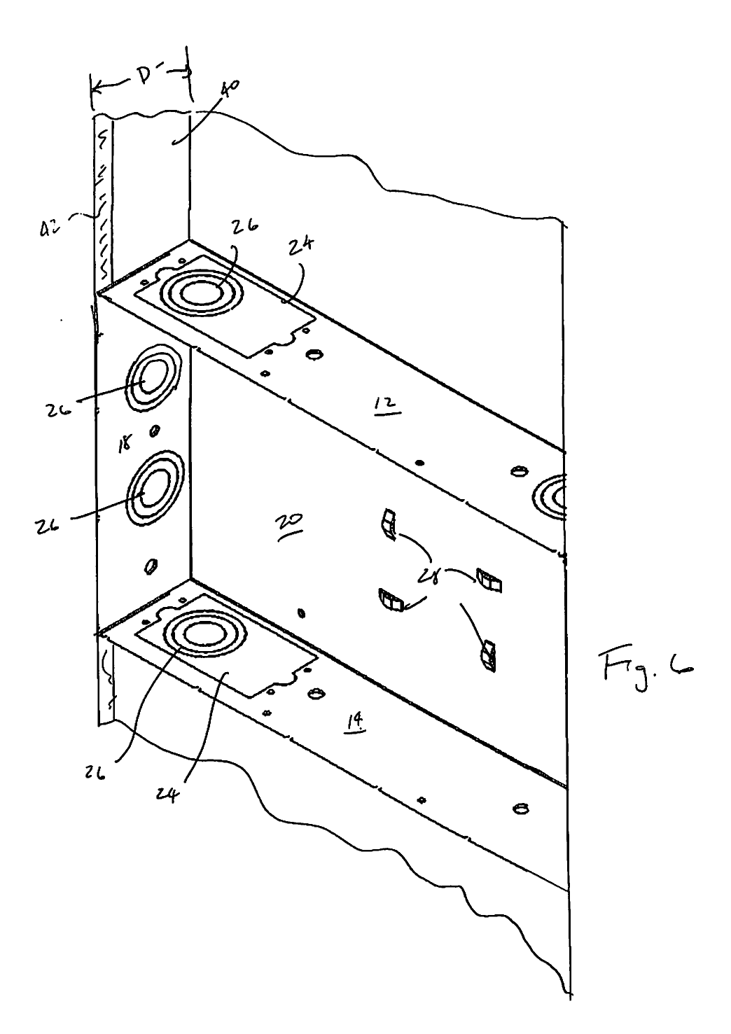

For example, as depicted in FIG. 5, where the enclosure 10 is to be installed in a wall of relatively greater thickness D+ (for example a 6 inch nominal wall thickness), portions 30, 32, 34, 36 can be left in place, so that enclosure 10 will offer a greater depth dimension considering the greater depth of studs 40 and drywall 42. For thinner walls (such as may be encountered with a nominal wall thickness of 4 inches), portions 30, 32, 34, 36 can be made to have a width of 2 inches and can be detached as depicted in FIG. 6 to provide an enclosure that fits within the available depth (D−).

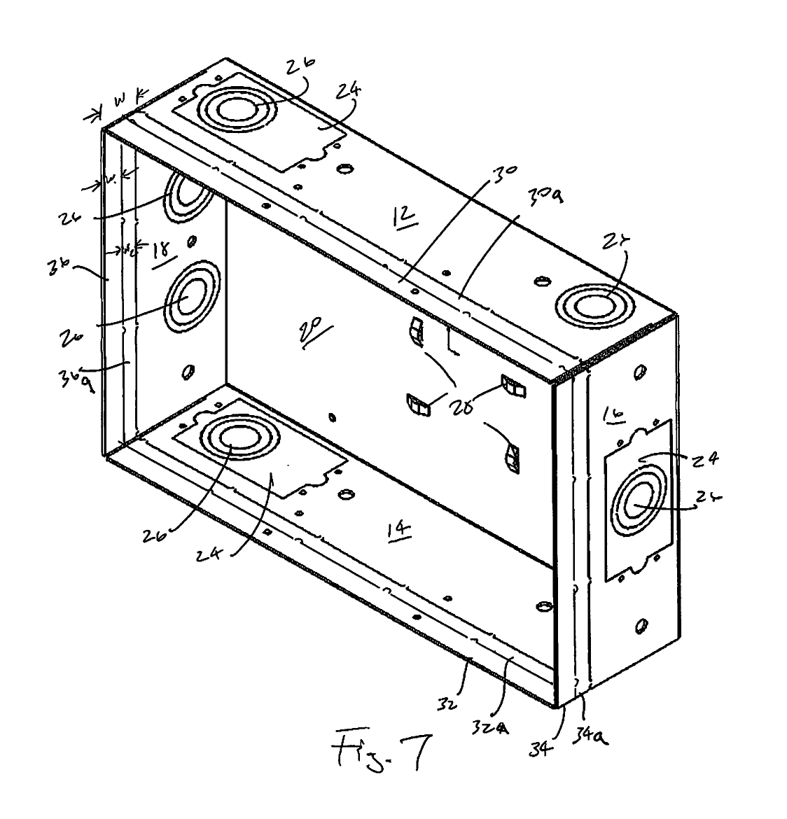

It will be appreciated that portions 30, 32, 34, 36 can be made to any width dimension W to account for any conceivable wall thickness that may be encountered. For example, in the case of energy efficient structures or sound attenuating walls using an 8 inch nominal wall thickness, portions 30, 32, 34, 36, could be made with a width dimension W of 4 inches. Moreover, multiple portions 30, 32, 34, 36, having width dimension W₁ and 30a, 32a, 34a, and 36a, having width dimension W₂ could be stacked as depicted in FIG. 7 so that multiple different wall thicknesses could be accommodated with the same enclosure.

The embodiments above are intended to be illustrative and not limiting. Additional embodiments are encompassed within the scope of the claims. Although the present invention has been described with reference to particular embodiments, those skilled in the art will recognize that changes may be made in form and detail without departing from the spirit and scope of the invention. For purposes of interpreting the claims for the present invention, it is expressly intended that the provisions of 35 U.S.C. 112(f), are not to be invoked unless the specific terms “means for” or “step for” are recited in a claim.

What is claimed is:

1. An enclosure adapted to be received in a stud-wall, the enclosure comprising:
a pair of opposing side walls, a pair of opposing end walls disposed adjacent and perpendicular to the side walls, a back wall, and an open front, each of the sides walls and each of the end walls having a permanently detachable portion along a margin thereof adjacent the open front.

2. The enclosure of claim 1, wherein at least one of the end walls has a permanently removable knock-out portion defined therein.

3. The enclosure of claim 1, wherein at least one of the side walls has a permanently removable knock-out portion defined therein.

4. The enclosure of claim 1, wherein each of the permanently detachable portions defines a predetermined width dimension corresponding to a difference between standard wall thickness dimensions.

5. The enclosure of claim 4, wherein the predetermined width dimension is two inches.

6. The enclosure of claim 4, wherein the predetermined width dimension is four inches.

7. The enclosure of claim 1, further comprising a plurality of mounting device attachments on the back wall.

8. The enclosure of claim 1, wherein each permanently detachable portion defines a plurality of separate permanently detachable portions.

9. A wall structure comprising:
a plurality of spaced-apart studs;
a drywall membrane on the spaced-apart studs; and
an enclosure disposed between a pair of the spaced-apart studs, the enclosure comprising a pair of opposing side walls, a pair of opposing end walls disposed adjacent and perpendicular to the side walls, a back wall, and an open front, each of the sides walls and each of the end walls having a permanently detachable portion along a margin thereof adjacent the open front.

10. The wall structure of claim 9, wherein at least one of the end walls of the enclosure has a permanently removable knock-out portion defined therein.

11. The wall structure of claim 9, wherein at least one of the side walls of the enclosure has a permanently removable knock-out portion defined therein.

12. The wall structure of claim 9, wherein each of the permanently detachable portions of the enclosure defines a predetermined width dimension corresponding to a difference between standard wall thickness dimensions.

13. The wall structure of claim 12, wherein the predetermined width dimension is two inches.

14. The wall structure of claim 12, wherein the predetermined width dimension is four inches.

15. The wall structure of claim 9, further comprising a plurality of mounting device attachments on the back wall of the enclosure.

16. The wall structure of claim 9, wherein each permanently detachable portion defines a plurality of separate permanently detachable portions.

17. A mounting system for an electronic display comprising:
an enclosure adapted to be received in a stud-wall, the enclosure comprising a pair of opposing side walls, a pair of opposing end walls disposed adjacent and perpendicular to the side walls, a back wall, and an open front, each of the sides walls and each of the end walls having a permanently detachable portion along a margin thereof adjacent the open front; and
a display mount attached to the back wall of the enclosure, the display mount adapted to receive an electronic display thereon.

18. The mounting system of claim 17, wherein at least one of the end walls of the enclosure has a permanently removable knock-out portion defined therein.

19. The mounting system of claim 17, wherein at least one of the side walls of the enclosure has a permanently removable knock-out portion defined therein.

20. The mounting system of claim 17, wherein each of the permanently detachable portions of the enclosure defines a predetermined width dimension corresponding to a difference between standard wall thickness dimensions.
